(19) United States
(12) Patent Application Publication
(10) Pub. No.: US 2016/0225748 A1
(43) Pub. Date: Aug. 4, 2016

(54) PACKAGE-ON-PACKAGE (POP) STRUCTURE

(71) Applicant: QUALCOMM Incorporated, San Diego, CA (US)

(72) Inventors: Hong Bok We, San Diego, CA (US); Jae Sik Lee, San Diego, CA (US); Kyu-Pyung Hwang, San Diego, CA (US)

(21) Appl. No.: 14/609,079

(22) Filed: Jan. 29, 2015

(51) Int. Cl. H01L 25/10; H01L 25/00

(52) U.S. Cl. CPC H01L 25/105; H01L 25/50; H01L 2225/1058

(57) ABSTRACT

A method for forming a package-on-package (POP) structure is disclosed. The method includes placing a post on a first integrated circuit (IC) package such that a solder coating disposed on a first surface of the post is between the post and a second surface of the first IC package. The post is placed at a distance from a die along a particular axis of the die. The particular axis is substantially parallel to the second surface. The first IC package includes the die. The method also includes forming a conductive path between a second IC package and the first IC package via the post and a solder bump. The solder bump is disposed between the post and the second IC package.

### I. FIELD

The present disclosure is generally related to package-on-package (POP) structures.

### II. DESCRIPTION OF RELATED ART

Advances in technology have resulted in smaller and more powerful computing devices. For example, there exist a variety of portable personal computing devices, including wireless telephones such as mobile and smart phones, tablets and laptop computers that are small, lightweight, and easily carried by users. These devices can communicate voice and data packets over wireless networks. Further, many such devices incorporate additional functionality such as a digital still camera, a digital video camera, a digital recorder, and an audio file player. Also, such devices can process executable instructions, including software applications, such as a web browser application, that can be used to access the Internet. As such, these devices can include significant computing capabilities.

Electronic devices, such as wireless telephones, may include integrated circuits in a package-on-package (POP) structure. A POP structure (e.g., a 2.5 D POP package) may include a first integrated circuit (IC) package, a second IC package, and an interposer layer. The first IC package and the second IC package may be co-planar. The first IC package and the second IC package may be parallel to (e.g., above or below) the interposer layer. The first IC package may include first solder bumps and the second IC package may include second solder bumps. The interposer layer may include through-silicon vias (TSVs). The TSVs may not be aligned with the solder bumps. The interposer layer may include complex metal traces to form paths between the solder bumps and the TSVs. The first IC package may be electrically coupled via the interposer layer to the second IC package. For example, one or more conductive paths from the first IC package to the second IC package may be formed via the first solder bumps, the metal traces, the TSVs, the metal traces, and the second solder bumps. Forming the metal traces may be complicated and expensive.

### III. SUMMARY

The present disclosure provides a package-on-package structure that includes a first integrated circuit (IC) package and a second IC package. The first IC package may include a die. The POP structure may include a post (e.g., a copper post) disposed on the first IC package. The post may have a solder coating disposed thereon. The post may be disposed on the first IC package such that a first portion of the solder coating may be between a first surface of the post and a second surface of the first IC package. In a particular example, the first surface of the post may be a bottom surface of the post and the second surface may be a top surface of a redistribution layer (RDL) of the first IC package. The post may be disposed at a distance from the die along a particular axis (e.g., a horizontal axis). For example, the post and the first portion of the solder coating may be disposed on a first portion of the RDL. The die may be attached, via a die bonding layer, to a second portion of the RDL. The first portion may be a particular distance from the second portion along the second surface (e.g., the top surface of the RDL). A solder bump may be disposed on the post. A portion of the post may extend into the solder bump. The second IC package may be disposed on the solder bump. The POP structure may include a conductive path between the first IC package and the second IC package through the solder bump and the post. In a particular example, the first IC package may be vertically below the second IC package.

During fabrication of a POP structure, one or more posts (e.g., copper posts) may be placed on a first IC package. For example, a first post (e.g., a copper post) and a second post (e.g., a copper post) may be placed on the first IC package. The one or more posts may be pre-coated with a solder coating. For example, the first post may be coated with a first solder coating and the second post may be coated with a second solder coating prior to being placed on the first IC package. At least a portion of the first solder coating may be between a first surface of the first post and a second surface of the first IC package. At least a portion of the second solder coating may be between the second post and the second surface of the first IC package. The first IC package may include a die. The first post may be placed a first distance from the die along a particular axis (e.g., a horizontal axis) of the die. The second post may be placed a second distance from the die along the particular axis.

Subsequent to placing the first post and the second post on the first IC package, a dielectric layer may be deposited on the first IC package. Trenches may be formed by removing portions of the dielectric layer. For example, a first trench may be formed to expose a top portion of the first post by removing a first portion of the dielectric layer and a second trench may be formed to expose a top portion of the second post by removing a second portion of the dielectric layer.

A first solder bump may be placed on the first post and a second solder bump may be placed on the second post. The second IC package may be placed on the first solder bump and the second solder bump. Alternatively, the first solder bump and the second solder bump may be pre-attached to the second IC package. For example, the second IC package may be coupled to a solder board that includes the first solder bump and the second solder bump. The second IC package may be placed on the first IC package so that the first solder bump aligns with (e.g., is placed on) the first post and the second solder bump aligns with (e.g., is placed on) the second post.

Reflow soldering may be performed subsequent to placing the second IC package on the first IC package. After the reflow soldering, material of the first solder bump may at least partially fill the first trench and material of the second solder bump may at least partially fill the second trench. The first post may extend into the first solder bump and the second post may extend into the second solder bump. The first solder coating and the first solder bump may form a stabilizing structure. For example, having the first post extend into the first solder bump may form a stronger coupling, as compared to the first post being attached to an outer surface of the first solder bump. Similarly, the second solder coating and the second solder bump may form another stabilizing structure.

In a particular aspect, a method for forming a package-on-package (POP) structure includes placing a post on a first integrated circuit (IC) package such that a solder coating disposed on a first surface of the post is between the post and a second surface of the first IC package. The post is placed at a distance from a die along a particular axis of the die. The particular axis is substantially parallel to the second surface. The first IC package includes the die. The method also includes forming a conductive path between a second IC package and the first IC package via the post and a solder bump. The solder bump is disposed between the post and the second IC package.

In another aspect, a package-on-package (POP) structure includes a first integrated circuit (IC) package and a second IC package. The first IC package includes a die. The POP structure also includes a post with solder coating disposed thereon. The post is disposed on the first IC package such that at least a portion of the solder coating is between a first surface of the post and a second surface of the first IC package. The post is disposed at a distance from the die along a particular axis of the die. The particular axis is substantially parallel to the second surface. The POP structure further includes a solder bump disposed between the post and the second IC package. The POP also includes a conductive path between the first IC package and the second IC package via the post and the solder bump.

In another aspect, a package-on-package (POP) structure includes a bottom integrated circuit (IC) package and a top IC package. The bottom IC package includes a die that includes a processor. The top IC package includes a memory. The POP structure also includes a copper post disposed on the bottom IC package. The copper post has a solder coating disposed thereon. At least a portion of the solder coating is between a first surface of the copper post and a second surface of the bottom IC package. The copper post is disposed at a distance from the die along a particular axis of the die. The particular axis is substantially parallel to the second surface. The POP structure further includes a solder bump disposed between the copper post and the top IC package. A portion of the copper post extends into the solder bump.

One particular advantage provided by at least one of the disclosed aspects is that a POP structure may exclude complex metal traces to form conductive paths between a first IC package and a solder bump coupled to a second IC package. For example, the POP structure may include a conductive path from a first integrated circuit (IC) package, via a post, to a solder bump coupled to a second IC package. The POP structure may be formed by placing the solder bump on the post and placing the second IC package on the solder bump. Alternatively, the solder bump may be pre-attached to the second IC package. The post may be placed on the first IC package so that the solder bump and the post are aligned when the second IC package is placed on the first IC package. The first IC package may be electrically coupled via the post to the solder bump. The POP structure may exclude (or reduce) complex metal traces between the solder bump and the first IC package. Another particular advantage may be that fabrication of the POP structure may be simplified and more cost-effective by using a pre-coated post, as compared to applying a solder coating to portions of the first IC package.

Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a block diagram of a package-on-package structure;

FIG. 2 is a diagram showing a side view of the POP structure of FIG. 1 during at least one stage of fabrication;

FIG. 3 is a diagram showing a side view of the POP structure of FIG. 1 during at least one stage of fabrication;

FIG. 4 is a diagram showing a side view of the POP structure of FIG. 1 during at least one stage of fabrication;

FIG. 5 is a diagram showing a side view of the POP structure of FIG. 1 during at least one stage of fabrication;

FIG. 6 is a flow chart of a particular illustrative embodiment of a method of forming the POP structure of FIG. 1;

FIG. 7 is a flow chart of another embodiment of a method of forming the POP structure of FIG. 1; and

FIG. 8 is a block diagram of an electronic device including a POP structure; and

FIG. 9 is a data flow diagram of a particular illustrative embodiment of a manufacturing process to manufacture electronic devices that include a POP structure.

### V. DETAILED DESCRIPTION

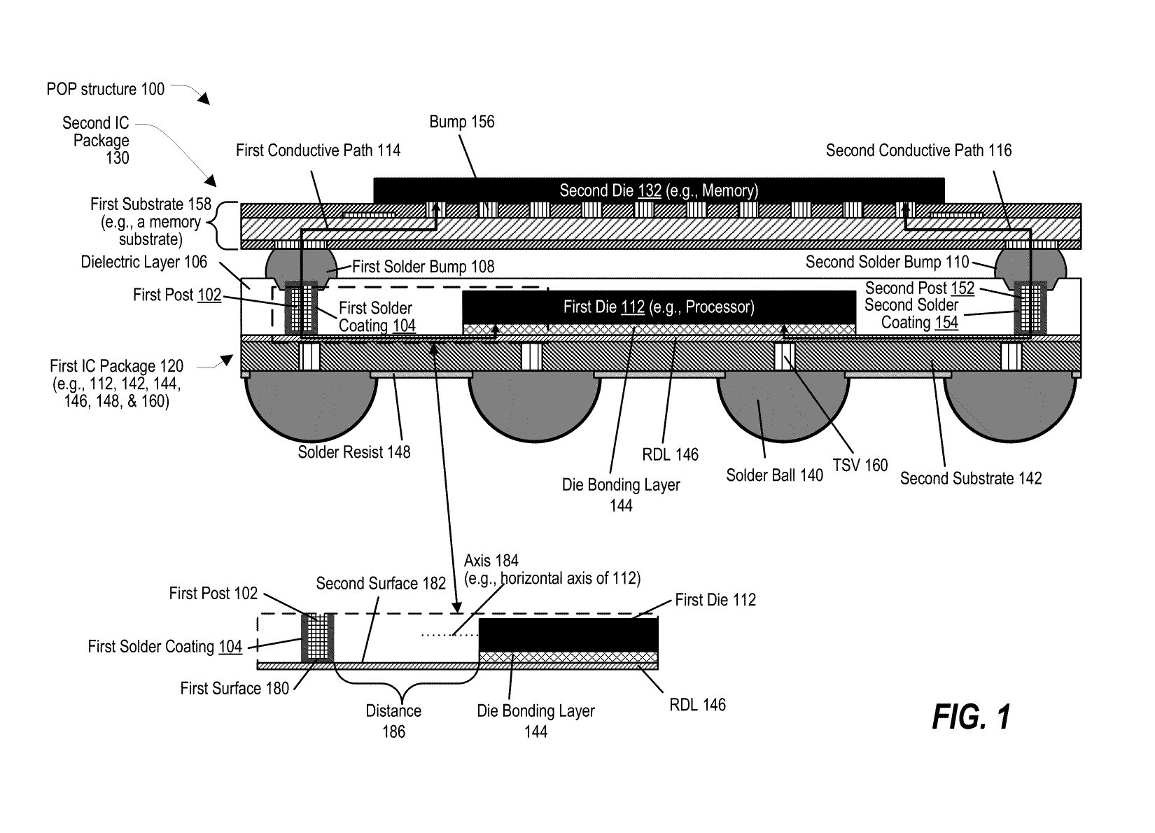

Referring to FIG. 1, a particular illustrative embodiment of a package-on-package (POP) structure is disclosed and generally designated 100. The POP structure 100 includes a first IC package 120 (e.g., a bottom IC package) and a second IC package 130 (e.g., a top IC package). The first IC package 120 may include a first die 112. The first die 112 may include at least one of an application processor (AP), a digital signal processor (DSP), a graphics processor, or another processor. The first IC package may include a second substrate 142. The second substrate 142 may include silicon (Si), an organic material, or both. The second substrate 142 may include one or more through-silicon vias (TSVs) (e.g., a TSV 160). The TSV 160 may include copper (Cu). One or more solder resists (e.g., a solder resist 148) may be disposed on a first surface of the second substrate 142. The solder resist 148 (e.g., a solder mask) may include a polymer.

One or more solder balls (e.g., a solder ball 140) may be disposed on the first surface of the second substrate 142. The solder ball 140 may include a fusible metal alloy. For example, the solder ball 140 may include at least one of tin, lead, copper, silver, bismuth, indium, zinc, or antimony. A redistribution layer (RDL) 146 may be disposed on a second surface of the second substrate 142. The RDL 146 may include one or more layers of metal. For example, the RDL 146 may include at least one of tin, copper, or nickel. The RDL 146 may include one or more layers of a polymer dielectric material. For example, the RDL 146 may include polyimide, benzocyclobutene (BCB), or both. The TSV 160 may couple the RDL 146 to the solder ball 140. For example, the TSV 160 may provide a conductive path between the RDL 146 and the solder ball 140. A die bonding layer 144 may be disposed on a first portion of a second surface 182 (e.g., a top surface) of the RDL 146. The die bonding layer 144 may include an epoxy adhesive, metal particles, or both. The first die 112 may be disposed on the die bonding layer 144. For example, the first die 112 may be attached, via the die bonding layer 144, to the first portion of the second surface 182.

The second IC package 130 may include a second die 132. The second die 132 may include a cache memory, another memory, or both. For example, the second die 132 may be disposed on a first substrate 158 (e.g., a memory substrate). The first substrate 158 may include at least one of silicon, sapphire, gallium, or arsenic. The first substrate 158 may include one or more bumps (e.g., a bump 156). The one or more bumps may provide a conductive path from the first substrate 158 to the second die 132. The bump 156 may include copper.

The POP structure 100 may include one or more posts (e.g., a first post 102 and a second post 152). A solder coating may be disposed on the one or more posts. For example, a first solder coating 104 may be disposed on the first post 102, a second solder coating 154 may be disposed on the second post 152, or both. The first solder coating 104, the second solder coating 154, or both, may include tin, gold, or another solder material. The first post 102 may be pre-coated with the first solder coating 104, the second post 152 may be pre-coated with the second solder coating 154, or both. For example, the first solder coating 104 (or the second solder coating 154) may be electroplated on the first post 102 (or the second post 152). As another example, the first post 102 (or the second post 152) may be dipped in the first solder coating 104 (or the second solder coating 154). In a particular embodiment, the first post 102 (or the second post 152) may be encapsulated in the first solder coating 104 (or the second solder coating 154). In an alternate embodiment, the first post 102 may be partially coated with the first solder coating 104, the second post 152 may be partially coated with the second solder coating 154, or both.

The first post 102, the second post 152, or both, may be disposed on the RDL 146. For example, the first post 102 may be disposed on a second portion of the second surface 182. At least a portion of the first solder coating 104 may be between a first surface 180 (e.g., a bottom surface) of the first post 102 and the second portion of the second surface 182. As another example, the second post 152 may be disposed on a third portion of the second surface 182. At least a portion of the second solder coating 154 may be between a surface (e.g., a bottom surface) of the second post 152 and the third portion of the second surface 182.

The first post 102 may be disposed on a first side of the first IC package 120. The second post 152 may be disposed on a second side of the first IC package 120. The first side may be opposite of the second side. For example, the second portion of the second surface 182 may be on an opposite side of the third portion of the second surface 182.

The first post 102 may be disposed at a first distance (e.g., a distance 186) from the first die 112 along an axis 184. The axis 184 may be a particular axis (e.g., a horizontal axis) of the first die 112. The distance 186 may correspond to a distance between the first portion of the second surface 182 and the second portion of the second surface 182. The axis 184 may be substantially parallel to the second surface 182. The second post 152 may be disposed at a second distance from the first die 112 along the axis 184. The second distance may correspond to a distance between the first portion of the second surface 182 and the third portion of the second surface 182.

The first post 102, the second post 152, or both, may have a first diameter (e.g., greater than or equal to approximately 75 micrometers and less than or equal to approximately 100 micrometers). The first post 102, the second post 152, or both, may have a first height (e.g., greater than or equal to approximately 75 micrometers and less than or equal to approximately 100 micrometers). In a particular embodiment, the first height may be greater than a height of the first die 112. The first post 102, the second post 152, or both, may have a cylindrical shape (e.g., a rectangular cylindrical shape, a circular cylindrical shape, an elliptical cylindrical shape, or a triangular cylindrical shape). The first post 102, the second post 152, or both, may include copper.

The POP structure 100 may include one or more solder bumps (e.g., a first solder bump 108 and a second solder bump 110). The first solder bump 108, the second solder bump 110, or both, may include a fusible metal alloy. For example, the first solder bump 108, the second solder bump 110, or both, may include at least one of tin, lead, copper, silver, bismuth, indium, zinc, or antimony. The first solder bump 108 may be disposed between the first post 102 and the second IC package 130. For example, the first solder bump 108 may be disposed between the first post 102 and the first substrate 158. A portion (e.g., a top portion) of the first post 102 may extend into the first solder bump 108. The second solder bump 110 may be disposed between the second post 152 and the second IC package 130. For example, the second solder bump 110 may be disposed between the second post 152 and the first substrate 158. A portion (e.g., a top portion) of the second post 152 may extend into the second solder bump 110.

The POP structure 100 may include a dielectric layer 106 (e.g., a molding layer). The dielectric layer 106 may include a photoresist. The dielectric layer 106 may include at least one of silicon, hafnium, zirconium, barium, or titanium. The dielectric layer 106 may be disposed on the first IC package 120. For example, the dielectric layer 106 may be disposed on at least a portion of the RDL 146, the first die 112, or a combination thereof. At least a portion (e.g., a bottom portion) of the first post 102, at least a portion (e.g., a bottom portion) of the second post 152, or both, may be embedded in the dielectric layer 106. The dielectric layer 106 may contact at least a portion of the first solder coating 104, a portion of the second solder coating 154, or both.

The POP structure 100 may include one or more conductive paths between the first IC package 120 and the second IC package 130. For example, the POP structure 100 may include a first conductive path 114 between the first die 112, via the first post 102, to the second die 132. The first conductive path 114 may pass through at least one of the die bonding layer 144, the RDL 146, the first solder coating 104, the first post 102, the first solder bump 108, or the first substrate 158. For example, the first conductive path 114 may pass through the die bonding layer 144, the RDL 146, the first solder coating 104, the first post 102, the first solder bump 108, and the first substrate 158. The first substrate 158 may be electrically coupled, via the first solder bump 108, to the first post 102. As another example, the POP structure 100 may include a second conductive path 116 between the first die 112, via the second post 152, to the second die 132. The second conductive path 116 may pass through at least one of the die bonding layer 144, the RDL 146, the second solder coating 154, the second post 152, the second solder bump 110, or the first substrate 158. For example, the second conductive path 116 may pass through the die bonding layer 144, the RDL 146, the second solder coating 154, the second post 152, the second solder bump 110, and the first substrate 158. The first substrate 158 may be electrically coupled, via the second solder bump 110, to the second post 152.

The POP structure 100 may thus include conductive paths between the first IC package 120, via the first post 102, the second post 152, or both, and solder bumps (e.g., the first solder bump 108, the second solder bump 110, or both) coupled to the second IC package 130. The POP structure 100 may include one or more conductive paths between the first die 112 and one or more solder balls (e.g., the solder ball 140) via the RDL 146 and one or more TSVs (e.g., the TSV 160). The POP structure 100 may include one or more conductive paths between the second die 132 and one or more solder balls (e.g., the solder ball 140) via the solder bumps (e.g., the first solder bump 108, the second solder bump 110, or both), the posts (e.g., the first post 102, the second post 152, or both), the RDL 146, and one or more TSVs (e.g., the TSV 160).

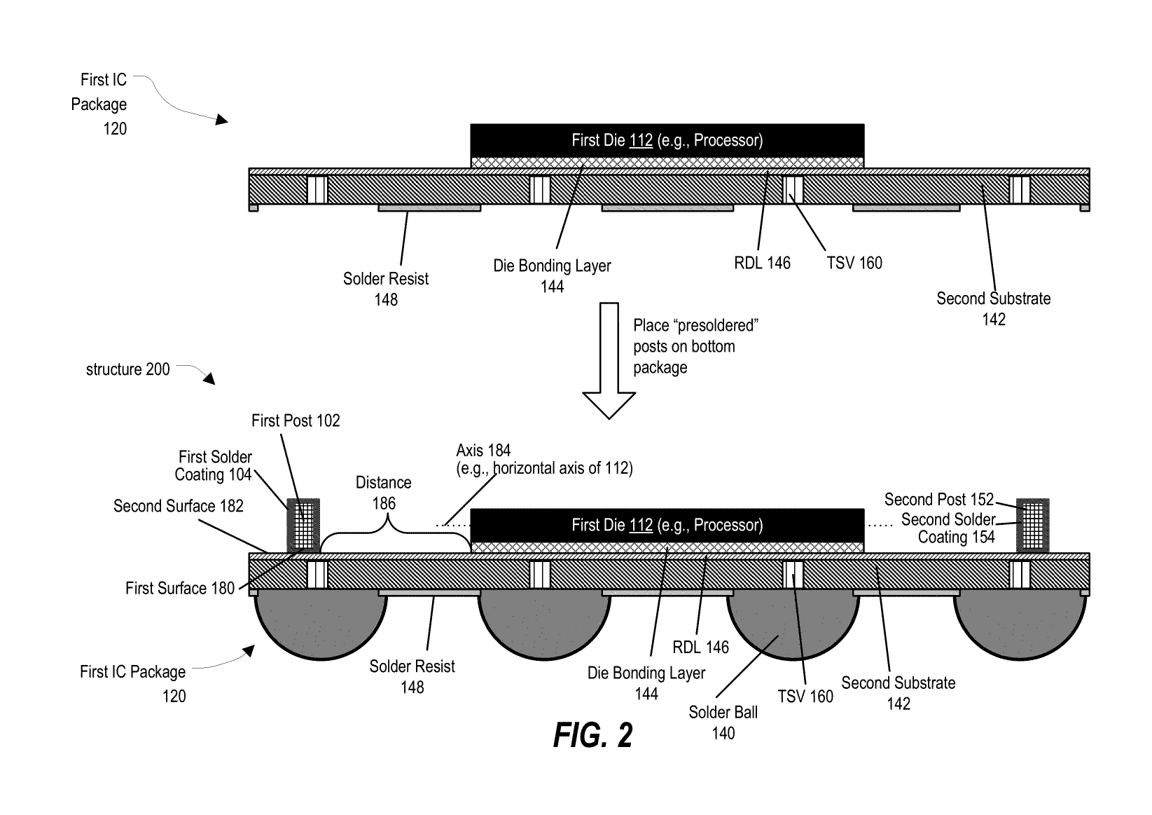

The POP structure 100 may be formed by placing the first solder bump 108 on the first post 102, by placing the second solder bump 110 on the second post 152, or both, as further described with reference to FIGS. 2-5. Alternatively, the first solder bump 108, the second solder bump 110, or both, may be pre-attached to the second IC package 130. The POP structure 100 may be formed by placing the first post 102, the second post 152, or both, on the first IC package 120) so that the first solder bump 108 is aligned with (e.g., placed on) the first post 102, the second solder bump 110 is aligned with (e.g., placed on) the second post 152, or both, subsequent to placing the second IC package 130 on the first IC package 120. The first post 102 may be electrically coupled to the first solder bump 108. The second post 152 may be electrically coupled to the second solder bump 110. The POP structure 100 may exclude complex traces between the solder bumps (e.g., the first solder bump 108, the second solder bump 110, or both) and the posts (e.g., the first post 102, the second post 152, or both) coupled to the first IC package 120. The POP structure 100 may thus exclude complex metal traces to form paths between the solder bumps (e.g., the first solder bump 108, the second solder bump 110, or both) and the first IC package 120.

Additionally, fabrication of the POP structure 100 may be simplified by using a pre-coated post (e.g., the first post 102, the second post 152, or both), as compared to applying a solder coating to portions of the first IC package 120. For example, applying a solder coating to portions of the first IC package 120 may include depositing a solder resist on the first IC package 120, removing portions of the solder resist using photolithography to expose portions of the first IC package 120, and depositing the solder coating on the exposed portions of the first IC package 120. Using a pre-coated post may include placing the post (e.g., the first post 102) on a copper post pad of the first IC package 120 and applying vibration to attach the first post 102 to the copper post pad.

FIGS. 2-5, as described herein, illustrate a side view of the POP structure 100 of FIG. 1 during particular stages of fabrication. In a particular embodiment, each structure illustrated in FIGS. 2-5 is formed during particular stages of fabricating an electronic device (e.g., a semiconductor device). The electronic device may include the POP structure 100.

Referring to FIG. 2, an illustrative diagram of a side view of a structure is shown and generally designated 200. The structure 200 may be formed during at least one stage in a process of fabrication of the POP structure 100 of FIG. 1. The structure 200 may be formed by placing one or more posts (e.g., the first post 102, the second post 152, or both) on the first IC package 120. For example, the first post 102, the second post 152, or both, may be placed on the RDL 146. The first die 112 may be attached, via the die bonding layer 144, to a first portion of the second surface 182 of the RDL 146. The first post 102 may be placed on a second portion of the second surface 182. At least a portion of the first solder coating 104 may be between the first surface 180 (e.g., a bottom surface) of the first post 102 and the second portion of the second surface 182. The second post 152 may be placed on a third portion of the second surface 182. At least a portion of the second solder coating 154 may be between a surface (e.g., a bottom surface) of the second post 152 and the third portion of the second surface 182.

The first post 102 may be placed on a first side of the first IC package 120. The second post 152 may be placed on a second side of the first IC package 120. The first side may be opposite of the second side. For example, the second portion of the second surface 182 may be on an opposite side of the third portion of the second surface 182.

The first post 102 may be disposed at the distance 186 from the first die 112 along the axis 184. The axis 184 may be a particular axis (e.g., a horizontal axis) of the first die 112. The distance 186 may correspond to a distance between the first portion of the second surface 182 and the second portion of the second surface 182. The axis 184 may be substantially parallel to the second surface 182. The second post 152 may be placed at a second distance from the first die 112 along the axis 184. The second distance may correspond to a distance between the first portion of the second surface 182 and the third portion of the second surface 182.

Vibration may be applied to the structure 200 to attach the first post 102, the second post 152, or both, to the RDL 146. In a particular embodiment, one or more copper post pads may be disposed on the RDL 146. In this embodiment, the first post 102 may be placed on a first copper post pad, the second post 152 may be placed on a second copper post pad, or both. Vibration may be applied to the structure 200 to attach the first post 102 to the first copper post pad, to attach the second post 152 to the second copper post pad, or both.

One or more solder balls (e.g., a solder ball 140) may be placed on the first IC package 120. For example, the RDL 146 may be disposed on a first surface of the second substrate 142. The solder ball 140 may be placed on a second surface of the second substrate 142. For example, an adhesive may be applied to the second surface of the second substrate 142 and the solder ball 140 may be placed on the adhesive. The second surface may be opposite of the first surface.

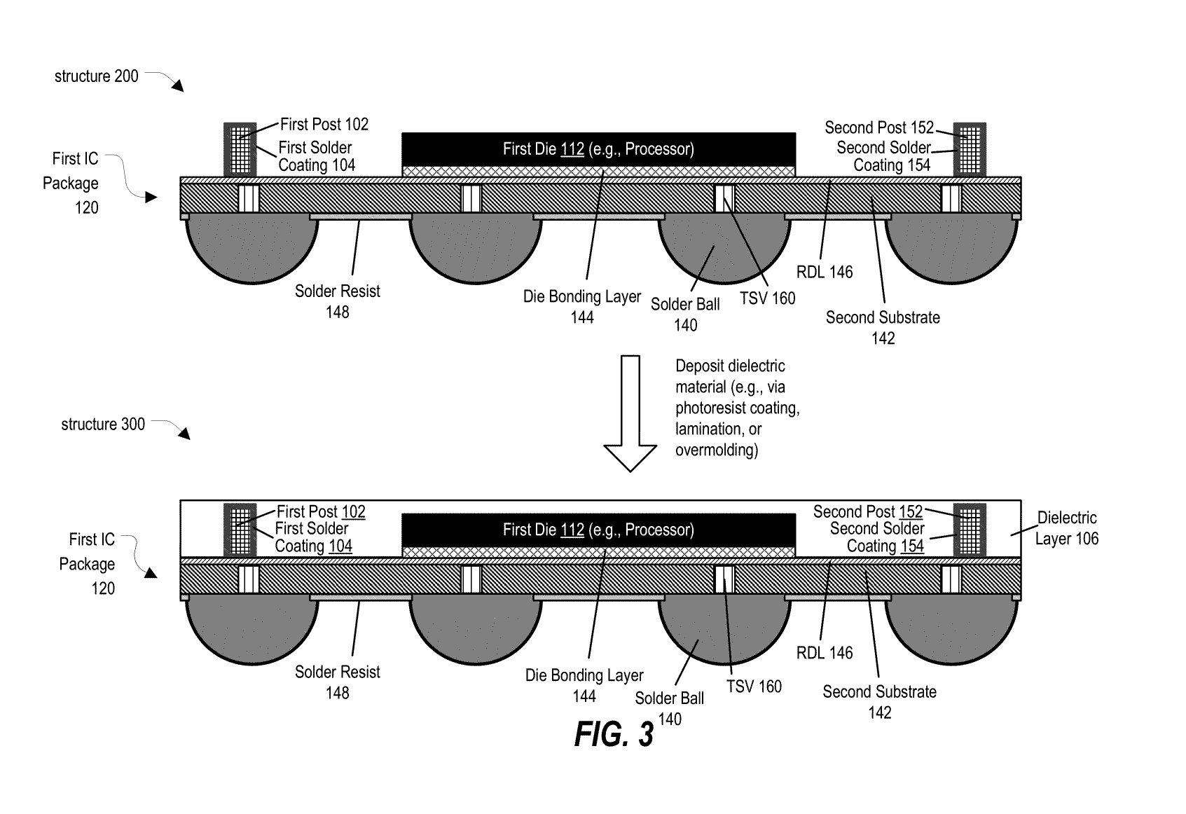

Referring to FIG. 3, an illustrative diagram of a side view of a structure is shown and generally designated 300. The structure 300 may be formed during at least one stage in a process of fabrication of the POP structure 100 of FIG. 1. The structure 300 may be formed by depositing the dielectric layer 106 on the structure 200 of FIG. 2. For example, the dielectric layer 106 may be deposited on the first IC package 120 subsequent to placing the first post 102, the second post 152, or both, on the first IC package 120. The dielectric layer 106 may be deposited on at least a portion of the RDL 146, the first die 112, or a combination thereof. The dielectric layer 106 may be deposited by applying a photoresist coating to the first IC package 120. In a particular embodiment, the dielectric layer 106 may be deposited by performing lamination or over-molding of the structure 200.

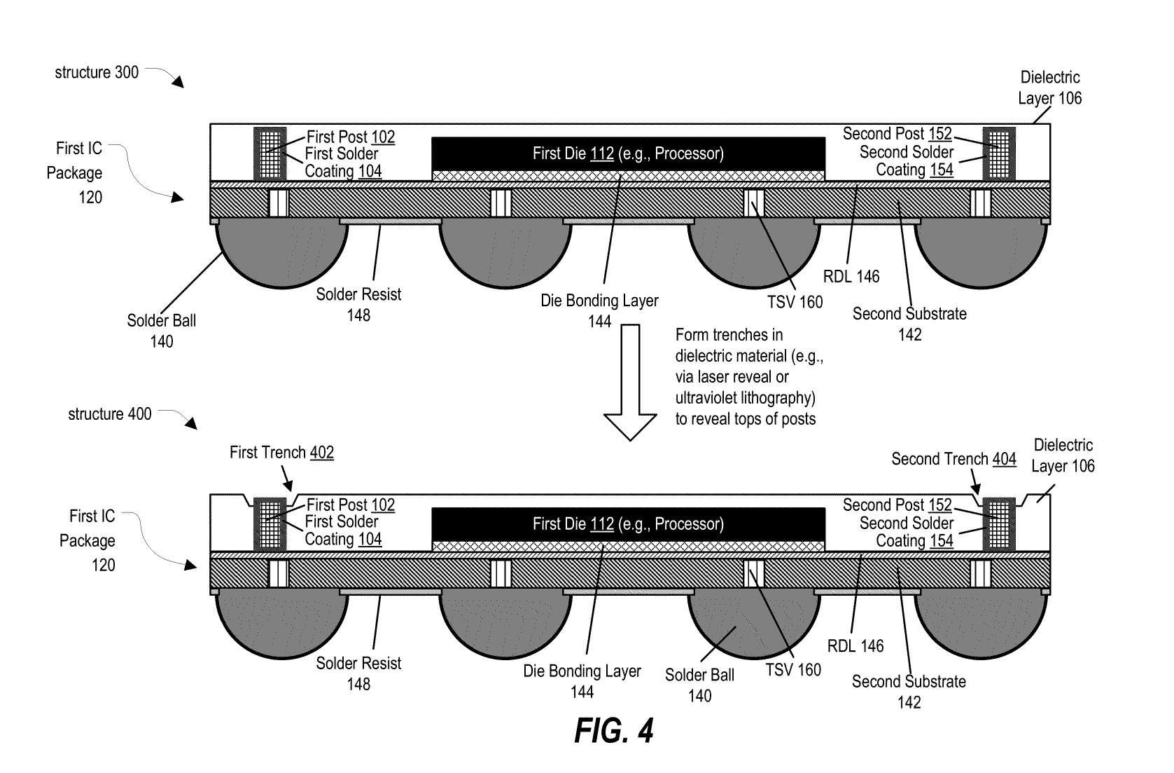

Referring to FIG. 4, an illustrative diagram of a side view of a structure is shown and generally designated 400. The structure 400 may be formed during at least one stage in a process of fabrication of the POP structure 100 of FIG. 1. The structure 400 may be formed by forming one or more trenches (e.g., a first trench 402, a second trench 404, or both) in the structure 300 of FIG. 3. For example, the first trench 402 may be formed in the dielectric layer 106 to expose a first portion (e.g., a top portion) of the first post 102. As another example, the second trench 404 may be formed in the dielectric layer 106 to expose a first portion (e.g., a top portion) of the second post 152. The first trench 402, the second trench 404, or both, may be formed by performing ultra-violet (UV) lithography (or laser reveal) to remove one or more portions of the dielectric layer 106. For example, a first portion of the dielectric layer 106 may be removed to expose the first portion of the first post 102. A second portion (e.g., a bottom portion) of the first post 102 may remain embedded in the dielectric layer 106. As another example, a second portion of the dielectric layer 106 may be removed to expose the first portion of the second post 152. A second portion (e.g., a bottom portion) of the second post 152 may remain embedded in the dielectric layer 106.

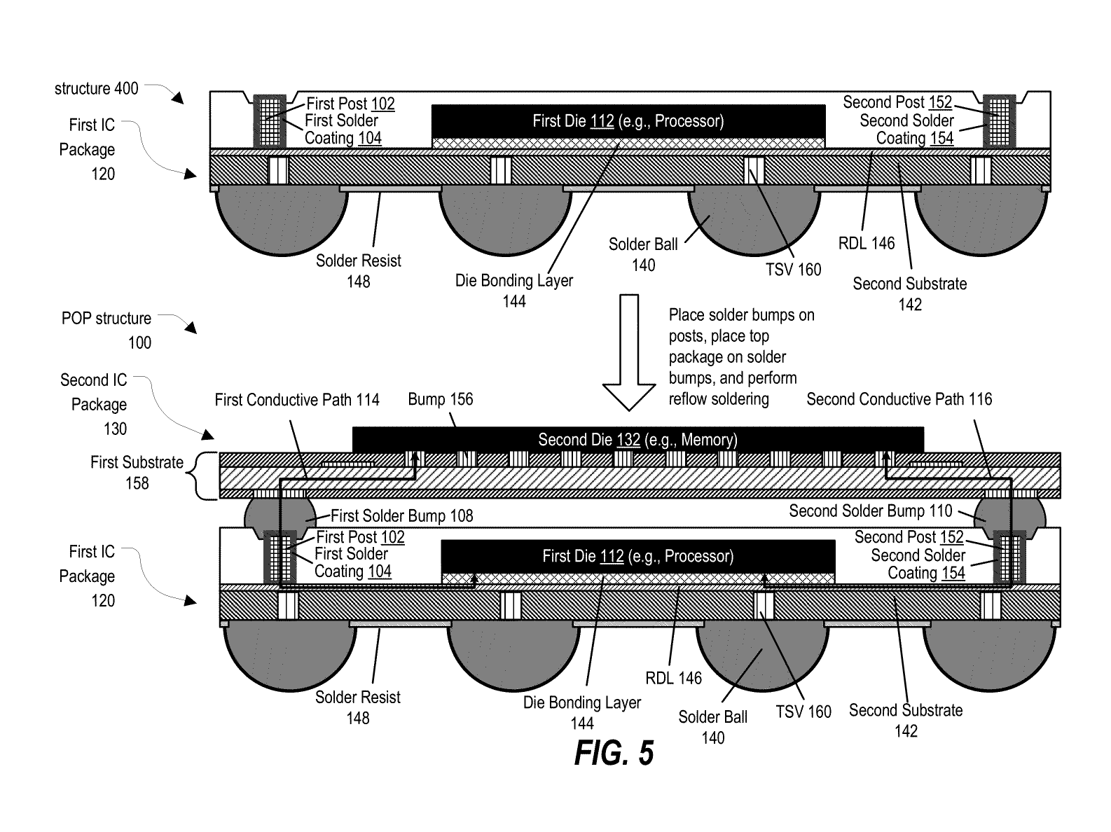

Referring to FIG. 5, an illustrative diagram of a side view of the POP structure 100 of FIG. 1 as formed during at least one stage in a process of fabrication is shown. The POP structure 100 may be formed by placing the second IC package 130 on the first IC package 120. For example, the first solder bump 108 may be placed on the first post 102. The second solder bump 110 may be placed on the second post 152. The second IC package 130 may be placed on the first solder bump 108, the second solder bump 110, or both.

In a particular embodiment, the first solder bump 108, the second solder bump 110, or both, may be pre-attached to the second IC package 130. For example, the second IC package 130 may be coupled to a solder board. The solder board may include the first solder bump 108, the second solder bump 110, or both. In this embodiment, the second IC package 130 may be placed on the structure 400 of FIG. 4 so that the first solder bump 108 is aligned with the first post 102, the second solder bump 110 is aligned with the second post 152, or both. For example, the first post 102 may be placed on the first IC package 120, as described with reference to FIG. 2, so that the first post 102 aligns with the first solder bump 108 when the second IC package 130 is placed on the structure 400 of FIG. 4. As another example, the second post 152 may be placed on the first IC package 120, as described with reference to FIG. 2, so that the second post 152 aligns with the second solder bump 110 when the second IC package is placed on the structure 400 of FIG. 4.

Reflow soldering may be performed to solder the second IC package 130 to the first IC package 120. For example, during the reflow soldering, the first solder bump 108 (or the second solder bump 110) may melt at least partially to fill the first trench 402 (or the second trench 404) of FIG. 4. Subsequent to the reflow soldering, material of the first solder bump 108 may at least partially fill the first trench 402, material of the second solder bump 110 may at least partially fill the second trench 404, or both. The first portion (e.g., the top portion) of the first post 102 may extend into the first solder bump 108. The first portion (e.g., the top portion) of the second post 152 may extend into the second solder bump 110.

The POP structure 100 formed as described with reference to FIGS. 2-5 may include one or more conductive paths between the first die 112 and the second die 132. For example, the POP structure 100 may include the first conductive path 114, the second conductive path 116, or both. The first die 112 may be electrically coupled, via the die bonding layer 144, the RDL 146, the first solder coating 104, and the first post 102, to the first solder bump 108. The first die 112 may be electrically coupled via the die bonding layer 144, the RDL 146, the second solder coating 154, and the second post 152, to the second solder bump 110. The second die 132 may be electrically coupled via the first substrate 158 to the first solder bump 108, to the second solder bump 110, or both.

The POP structure 100 may thus enable solder bumps (e.g., the first solder bump 108, the second solder bump 110, or both) to be coupled, via the first post 102, the second post 152, or both, to the first IC package 120. The POP structure 100 may thus exclude complex metal traces to form paths between the solder bumps (e.g., the first solder bump 108, the second solder bump 110, or both) and the first IC package 120. Additionally, fabrication of the POP structure 100 may be simplified by using a pre-coated post (e.g., the first post 102, the second post 152, or both), as compared to applying a solder coating to portions of the first IC package 120.

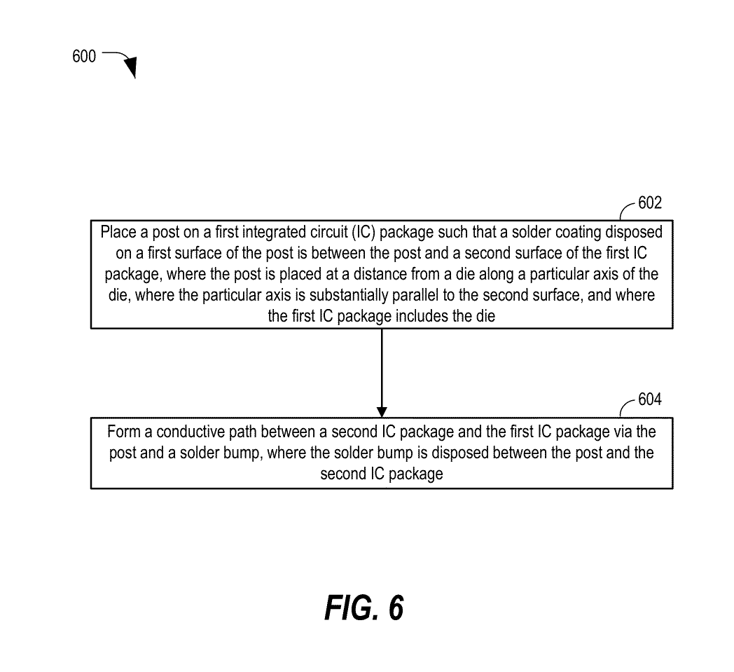

FIG. 6 is a flow chart illustrating a particular embodiment of a method 600 of forming the POP structure 100 of FIG. 1. The method 600 includes placing a post on a first integrated circuit (IC) package such that a solder coating disposed on a first surface of the post is between the post and a second surface of the first IC package, at 602. For example, the POP structure 100 of FIG. 1 may be formed by placing the first post 102 on the first IC package 120 such that at least a portion of the first solder coating 104 disposed on the first surface 180 is between the first post 102 and the second surface 182, as described with reference to FIG. 2. The first post 102 may be placed at the distance 186 from the first die 112 along the axis 184, as described with reference to FIG. 2. The axis 184 may be substantially parallel to the second surface 182, as described with reference to FIG. 2. The first IC package 120 may include the first die 112.

The method 600 also includes forming a conductive path between a second IC package and the first IC package via the post and a solder bump, at 604. For example, forming the POP structure 100 of FIG. 1 may include forming the first conductive path 114 via the first post 102 and the first solder bump 108, as described with reference to FIGS. 3-5. The first solder bump 108 may be disposed between the first post 102 and the second IC package, as described with reference to FIG. 5.

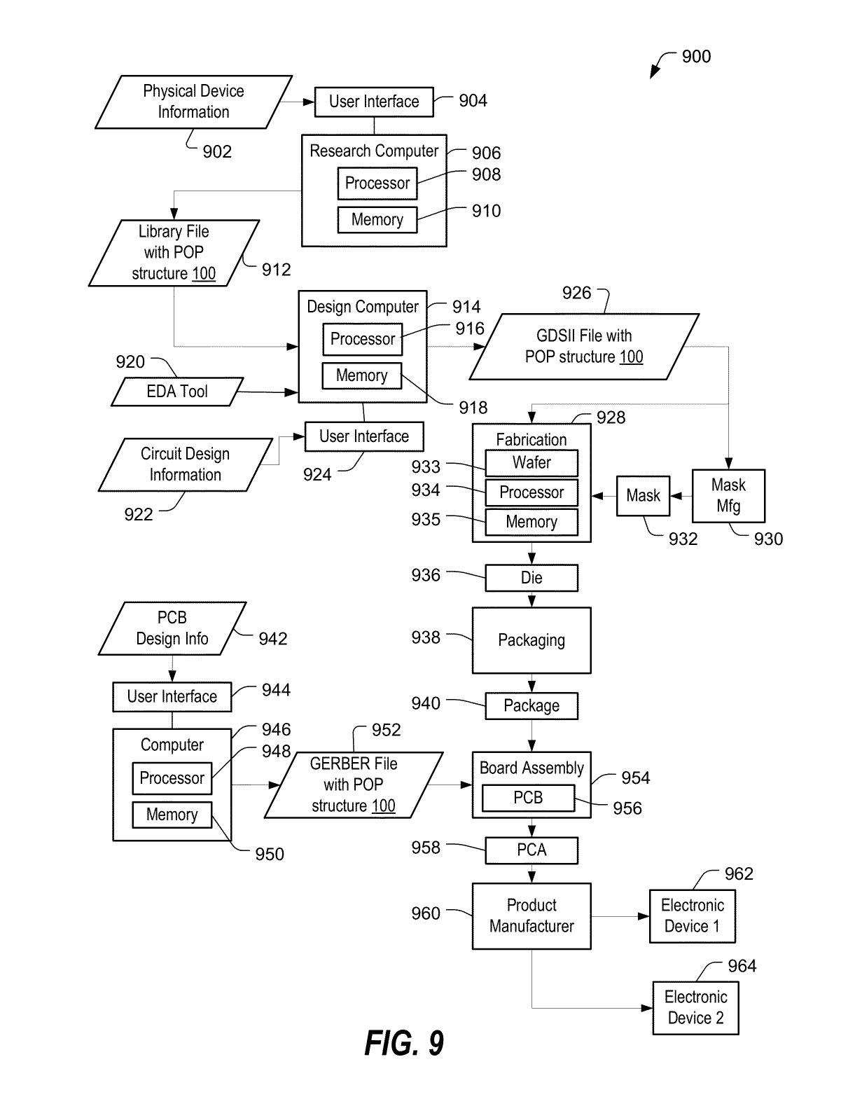

The method 600 of FIG. 6 may be implemented by a field-programmable gate array (FPGA) device, an application-specific integrated circuit (ASIC), a processing unit such as a central processing unit (CPU), a digital signal processor (DSP), a controller, another hardware device, firmware device, or any combination thereof. As an example, the method 600 of FIG. 6 can be performed by a processor that executes instructions, as described with respect to FIG. 9.

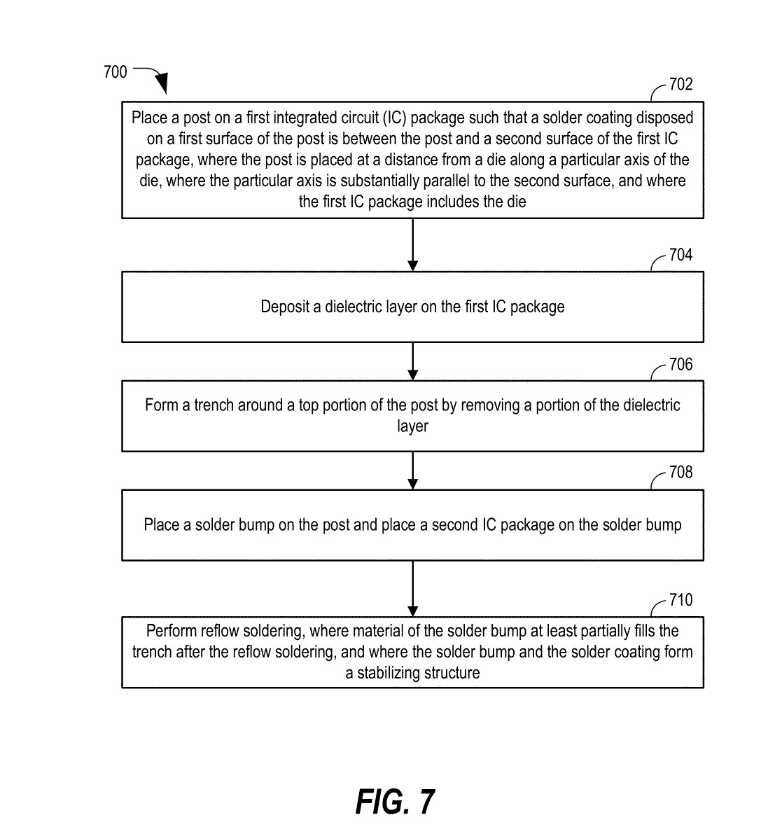

FIG. 7 is a flow chart illustrating another embodiment of a method of forming the POP structure 100 of FIG. 1. The method 700 includes placing a post on a first integrated circuit (IC) package such that a solder coating disposed on a first surface of the post is between the post and a second surface of the first IC package, at 702. For example, the POP structure 100 of FIG. 1 may be formed by placing the first post 102 on the first IC package 120 such that at least a portion of the first solder coating 104 disposed on the first surface 180 is between the first post 102 and the second surface 182, as described with reference to FIG. 2. The first post 102 may be placed at the distance 186 from the first die 112 along the axis 184, as described with reference to FIG. 2. The axis 184 may be substantially parallel to the second surface 182, as described with reference to FIG. 2. The first IC package 120 may include the first die 112.

The method 700 also includes depositing a dielectric layer on the first IC package, at 704. For example, the POP structure 100 of FIG. 1 may be formed by depositing the dielectric layer 106 on the first IC package 120, as described with reference to FIG. 3.

The method 700 further includes forming a trench around a top portion of the post by removing a portion of the dielectric layer, at 706. For example, the POP structure 100 of FIG. 1 may be formed by forming the first trench 402 around a top portion of the first post 102 by removing a first portion of the dielectric layer 106, as described with reference to FIG. 4.

The method 700 also includes placing a solder bump on the post and placing a second IC package on the solder bump, at 708. For example, the POP structure 100 of FIG. 1 may be formed by placing the first solder bump 108 on the first post 102, as described with reference to FIG. 5. The second IC package 130 may be placed on the first solder bump 108, as described with reference to FIG. 5.

The method 700 further includes performing reflow soldering, at 710. For example, the POP structure 100 of FIG. 1 may be formed by performing reflow soldering subsequent to placing the second IC package 130 on the first solder bump 108, as described with reference to FIG. 5. After the reflow solder, material of the first solder bump 108 may at least partially fill the first trench 402, as described with reference to FIG. 5. The first solder bump 108 and the first solder coating 104 may form a stabilizing structure.

The method 700 of FIG. 7 may be implemented by a field-programmable gate array (FPGA) device, an application-specific integrated circuit (ASIC), a processing unit such as a central processing unit (CPU), a digital signal processor (DSP), a controller, another hardware device, firmware device, or any combination thereof. As an example, the method 700 of FIG. 7 can be performed by a processor that executes instructions, as described with respect to FIG. 9.

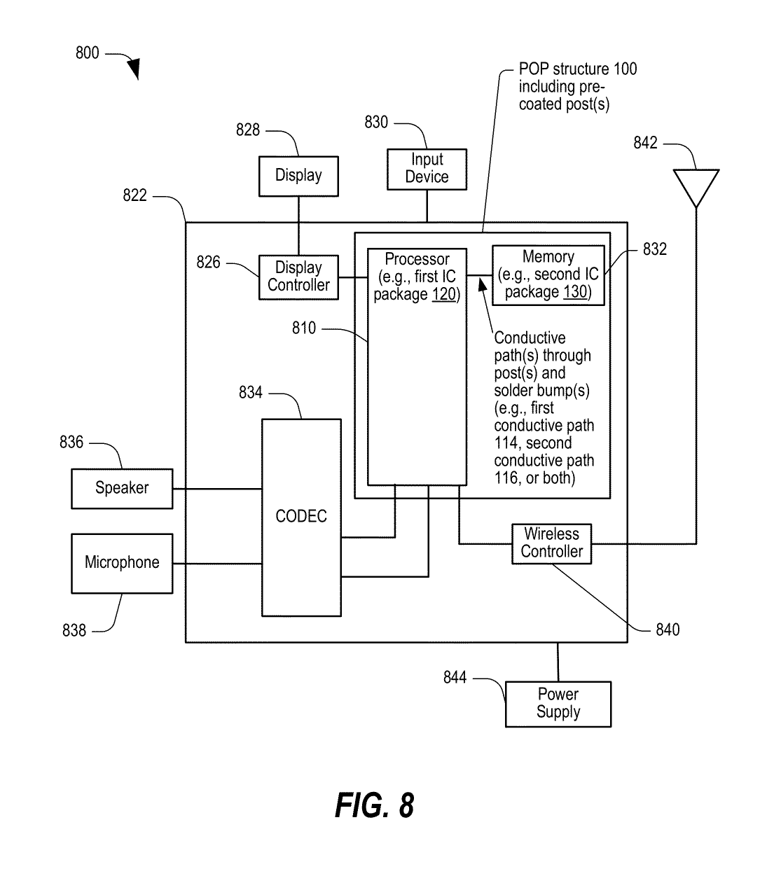

Referring to FIG. 8, a block diagram of a particular illustrative embodiment of an electronic device is depicted and generally designated 800. The device 800 includes a processor 810, such as a digital signal processor (DSP), coupled to a memory 832. In a particular embodiment, the processor 810 may correspond to the first IC package 120 of FIG. 1, and the memory 832 may correspond to the second IC package 130. For example, the device 800 may include the POP structure 100 of FIG. 1. The first IC package 120 may be included in or coupled to the processor 810. The second IC package 130 may be included in or coupled to the memory 832. The processor 810 may be coupled to the memory 832. For example, the POP structure 100 may include one or more conductive paths (e.g., the first conductive path 114, the second conductive path 116, or both) between the processor 810 and the memory 832. In an illustrative embodiment, the POP structure 100 may be formed according to one or more of the methods or operations described with reference to FIGS. 2-7.

FIG. 8 also shows a display controller 826 that is coupled to the processor 810 and to a display 828. A coder/decoder (CODEC) 834 can also be coupled to the processor 810. A speaker 836 and a microphone 838 can be coupled to the CODEC 834.

FIG. 8 also indicates that a wireless controller 840 can be coupled to the processor 810 and to a wireless antenna 842. In a particular embodiment, the processor 810, the display controller 826, the memory 832, the CODEC 834, and the wireless controller 840 are included in a system-in-package or system-on-chip device 822. In a particular embodiment, an input device 830 and a power supply 844 are coupled to the system-on-chip device 822. Moreover, in a particular embodiment, as illustrated in FIG. 8, the display 828, the input device 830, the speaker 836, the microphone 838, the wireless antenna 842, and the power supply 844 are external to the system-on-chip device 822. However, each of the display 828, the input device 830, the speaker 836, the microphone 838, the wireless antenna 842, and the power supply 844 can be coupled to a component of the system-on-chip device 822, such as an interface or a controller.

In conjunction with the described embodiments, an apparatus is disclosed that may include first means for packaging a first integrated circuit IC that includes a die. For example, the means for packaging may include the first IC package 120 of FIG. 1, one or more other devices or circuits configured to package an IC, or a combination thereof. The first IC package 120 may include the first die 112 of FIG. 1.

The apparatus may also include second means for packaging a second IC. For example, the second means for packaging may include the second IC package 130, one or more other devices or circuits configured to package an IC, or a combination thereof.

The apparatus may further include first means for connecting the first means for packaging to the second means for packaging. For example, the apparatus may include the first post 102, the second post 152 of FIG. 1, one or more other devices or circuits configured to connect the first IC package to the second IC package, or a combination thereof. The first post 102, the second post 152, or both, may connect the first IC package 120 to the second IC package 130, as described with reference to FIG. 1. The first post 102 may have the first solder coating 104 disposed thereon. At least a portion of the first solder coating 104 may be disposed between the first surface 180 and the second surface 182, as described with reference to FIG. 1. The first post 102 may be disposed at the distance 186 from the first die 112 along the axis 184, as described with reference to FIG. 1. The second post 152 may have the second solder coating 154 disposed thereon. At least a portion of the second solder coating 154 may be disposed between a first surface of the second post 152 and the second surface 182, as described with reference to FIG. 1. The second post 152 may be disposed at a second distance from the first die 112 along the axis 184, as described with reference to FIG. 1. The axis 184 may be substantially parallel to the second surface 182.

The apparatus may also include second means for connecting the first means for packaging to the second means for packaging. For example, the apparatus may include the first solder bump 108, the second solder bump 110 of FIG. 1, one or more other devices or circuits configured to connect the first IC package to the second IC package, or a combination thereof. The first solder bump 108 may be disposed on the first post 102. The second solder bump 110 may be disposed on the second post 152.

The foregoing disclosed devices and functionalities may be designed and configured into computer files (e.g. RTL, GDSII, GERBER, etc.) stored on computer readable media. Some or all such files may be provided to fabrication handlers who fabricate devices based on such files. Resulting products include semiconductor wafers that are then cut into semiconductor die and packaged into a semiconductor chip. The chips are then employed in devices described above. FIG. 9 depicts a particular illustrative embodiment of an electronic device manufacturing process 900.

Physical device information 902 is received at the manufacturing process 900, such as at a research computer 906. The physical device information 902 may include design information representing at least one physical property of a semiconductor device, such as the POP structure 100. For example, the physical device information 902 may include physical parameters, material characteristics, and structure information that is entered via a user interface 904 coupled to the research computer 906. The research computer 906 includes a processor 908, such as one or more processing cores, coupled to a computer readable medium such as a memory 910. The memory 910 may store computer readable instructions that are executable to cause the processor 908 to transform the physical device information 902 to comply with a file format and to generate a library file 912.

In a particular embodiment, the library file 912 includes at least one data file including the transformed design information. For example, the library file 912 may include a library of semiconductor devices including a device that includes the POP structure 100, that is provided for use with an electronic design automation (EDA) tool 920.

The library file 912 may be used in conjunction with the EDA tool 920 at a design computer 914 including a processor 916, such as one or more processing cores, coupled to a memory 918. The EDA tool 920 may be stored as processor executable instructions at the memory 918 to enable a user of the design computer 914 to design a circuit including the POP structure 100 of the library file 912. For example, a user of the design computer 914 may enter circuit design information 922 via a user interface 924 coupled to the design computer 914. The circuit design information 922 may include design information representing at least one physical property of a semiconductor device, such as the POP structure 100. To illustrate, the circuit design property may include identification of particular circuits and relationships to other elements in a circuit design, positioning information, feature size information, interconnection information, or other information representing a physical property of a semiconductor device.

The design computer 914 may be configured to transform the design information, including the circuit design information 922, to comply with a file format. To illustrate, the file formation may include a database binary file format representing planar geometric shapes, text labels, and other information about a circuit layout in a hierarchical format, such as a Graphic Data System (GDSII) file format. The design computer 914 may be configured to generate a data file including the transformed design information, such as a GDSII file 926 that includes information describing the POP structure 100 in addition to other circuits or information. To illustrate, the data file may include information corresponding to a system-on-chip (SOC) that includes the POP structure 100, and that also includes additional electronic circuits and components within the SOC.

The GDSII file 926 may be received at a fabrication process 928 to manufacture the POP structure according to transformed information in the GDSII file 926. For example, a device manufacture process may include providing the GDSII file 926 to a mask manufacturer 930 to create one or more masks, such as masks to be used with photolithography processing, illustrated as a representative mask 932. The mask 932 may be used during the fabrication process to generate one or more wafers 934, which may be tested and separated into dies, such as a representative die 936. The die 936 includes a circuit including a device that includes the POP structure 100.

The die 936 may be provided to a packaging process 938 where the die 936 is incorporated into a representative package 940. For example, the package 940 may include the single die 936 or multiple dies, such as a system-in-package (SiP) arrangement. The package 940 may be configured to conform to one or more standards or specifications, such as Joint Electron Device Engineering Council (JEDEC) standards.

Information regarding the package 940 may be distributed to various product designers, such as via a component library stored at a computer 946. The computer 946 may include a processor 948, such as one or more processing cores, coupled to a memory 950. A printed circuit board (PCB) tool may be stored as processor executable instructions at the memory 950 to process PCB design information 942 received from a user of the computer 946 via a user interface 944. The PCB design information 942 may include physical positioning information of a packaged semiconductor device on a circuit board, the packaged semiconductor device corresponding to the package 940 including the POP structure 100.

The computer 946 may be configured to transform the PCB design information 942 to generate a data file, such as a GERBER file 952 with data that includes physical positioning information of a packaged semiconductor device on a circuit board, as well as layout of electrical connections such as traces and vias, where the packaged semiconductor device corresponds to the package 940 including the POP structure 100. In other embodiments, the data file generated by the transformed PCB design information may have a format other than a GERBER format.

The GERBER file 952 may be received at a board assembly process 954 and used to create PCBs, such as a representative PCB 956, manufactured in accordance with the design information stored within the GERBER file 952. For example, the GERBER file 952 may be uploaded to one or more machines to perform various steps of a PCB production process. The PCB 956 may be populated with electronic components including the package 940 to form a representative printed circuit assembly (PCA) 958.

The PCA 958 may be received at a product manufacture process 960 and integrated into one or more electronic devices, such as a first representative electronic device 962 and a second representative electronic device 964. As an illustrative, non-limiting example, the first representative electronic device 962, the second representative electronic device 964, or both, may be selected from the group of a set top box, a music player, a video player, an entertainment unit, a navigation device, a communications device, a personal digital assistant (PDA), a fixed location data unit, and a computer, into which the POP structure 100 is integrated. As another illustrative, non-limiting example, one or more of the electronic devices 962 and 964 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 9 illustrates remote units according to teachings of the disclosure, the disclosure is not limited to these illustrated units. Embodiments of the disclosure may be suitably employed in any device which includes active integrated circuitry including memory and on-chip circuitry.

A device that includes the POP structure 100 may be fabricated, processed, and incorporated into an electronic device, as described in the illustrative process 900. One or more aspects of the embodiments disclosed with respect to FIGS. 1-8 may be included at various processing stages, such as within the library file 912, the GDSII file 926, and the GERBER file 952, as well as stored at the memory 910 of the research computer 906, the memory 918 of the design computer 914, the memory 950 of the computer 946, the memory of one or more other computers or processors (not shown) used at the various stages, such as at the board assembly process 954, and also incorporated into one or more other physical embodiments such as the mask 932, the die 936, the package 940, the PCA 958, other products such as prototype circuits or devices (not shown), or any combination thereof. Although various representative stages of production from a physical device design to a final product are depicted, in other embodiments fewer stages may be used or additional stages may be included. Similarly, the process 900 may be performed by a single entity or by one or more entities performing various stages of the process 900.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A method for forming a package-on-package (POP) structure, the method comprising:
placing a post on a first integrated circuit (IC) package such that a solder coating disposed on a first surface of the post is between the post and a second surface of the first IC package, wherein the post is placed at a distance from a die along a particular axis of the die, wherein the particular axis is substantially parallel to the second surface, and wherein the first IC package includes the die; and
forming a conductive path between a second IC package and the first IC package via the post and a solder bump, wherein the solder bump is disposed between the post and the second IC package.

2. The method of claim 1, wherein a diameter of the post is greater than or equal to approximately 75 micrometers.

3. The method of claim 1, wherein a diameter of the post is less than or equal to approximately 100 micrometers.

4. The method of claim 1, wherein the post comprises copper.

5. The method of claim 1, wherein the solder coating comprises tin, gold, or both.

6. The method of claim 1, wherein forming the conductive path comprises depositing a dielectric layer on the first IC package subsequent to placing the post on the first IC package.

7. The method of claim 6, wherein forming the conductive path further comprises forming a trench to expose a top portion of the post by removing a portion of the dielectric layer, wherein the solder bump is placed on the post subsequent to forming the trench.

8. The method of claim 7, wherein the portion of the dielectric layer is removed by ultraviolet lithography.

9. The method of claim 7, wherein forming the conductive path further comprises soldering the second IC package to the first IC package by reflow soldering, wherein, after the reflow soldering, material of the solder bump at least partially fills the trench.

10. The method of claim 1, wherein forming the conductive path comprises:
placing the solder bump on the post, and
placing the second IC package on the solder bump.

11. The method of claim 1, wherein the second IC package is coupled to a solder board that includes the solder bump, and wherein forming the conductive path comprises placing the second IC package on the first IC package so that the solder bump is placed on the post.

12. The method of claim 1, further comprising placing multiple pre-coated posts on the first IC package prior to forming the conductive path.

13. A package-on-package (POP) structure comprising:
a first integrated circuit (IC) package including a die;
a second IC package;
a post with a solder coating disposed thereon, the post disposed on the first IC package such that at least a portion of the solder coating is between a first surface of the post and a second surface of the first IC package, wherein the post is disposed at a distance from the die along a particular axis of the die, and wherein the particular axis is substantially parallel to the second surface;
a solder bump disposed between the post and the second IC package; and
a conductive path between the first IC package and the second IC package via the post and the solder bump.

14. The POP structure of claim 13, wherein a portion of the post extends into the solder bump.

15. The POP structure of claim 13, wherein the post is disposed on a first side of the first IC package.

16. The POP structure of claim 15, further comprising a second post disposed on a second side of the first IC package opposite the first side, the second post having a second solder coating disposed thereon.

17. The POP structure of claim 16, further comprising a second solder bump disposed between the second post and the second IC package, wherein a portion of the second post extends into the second solder bump.

18. The POP structure of claim 16, further comprising a second conductive path between the first IC package and the second IC package through at least the second post.

19. The POP structure of claim 13, wherein the first IC package and the second IC package are integrated into a computer, a communications device, a personal digital assistant (PDA), an entertainment unit, a navigation device, a music player, a video player, a fixed location data unit, a set top box, or a combination thereof.

20. The POP structure of claim 13, wherein the die includes a processor.

21. The POP structure of claim 20, wherein the processor comprises an application processor, a digital signal processor, a graphics processor, or any combination thereof.

22. The POP structure of claim 13, further comprising a dielectric material disposed on the die, wherein the dielectric material contacts at least a second portion of the solder coating.

23. The POP structure of claim 13, wherein the first IC package further comprises a die bonding layer, a redistribution layer (RDL), and a substrate.

24. The POP structure of claim 13, wherein the second IC package comprises a second die that includes a memory.

25. The POP structure of claim 24, wherein the memory comprises a cache memory.

26. The POP structure of claim 24, wherein the second IC package further comprises a memory substrate electrically coupled to the post via the solder bump.

27. A package-on-package (POP) structure comprising:
a bottom integrated circuit (IC) package comprising a die that includes a processor;
a top IC package comprising a memory;
a copper post disposed on the bottom IC package, the copper post having a solder coating disposed thereon, wherein at least a portion of the solder coating is between a first surface of the copper post and a second surface of the bottom IC package, wherein the copper post is disposed at a distance from the die along a particular axis of the die, and wherein the particular axis is substantially parallel to the second surface; and
a solder bump disposed between the copper post and the top IC package, wherein a portion of the copper post extends into the solder bump.

28. The POP structure of claim 27, wherein the bottom IC package and the top IC package are integrated into a computer, a communications device, a personal digital assistant (PDA), an entertainment unit, a navigation device, a music player, a video player, a fixed location data unit, a set top box, or a combination thereof.

29. An apparatus comprising:
first means for packaging a first integrated circuit (IC) that includes a die;
second means for packaging a second IC;
first means for connecting the first means for packaging to the second means for packaging, the first means for connecting having a solder coating disposed thereon, wherein at least a portion of the solder coating is disposed between a first surface of the first means for connecting and a second surface of the first means for packaging, wherein the first means for connecting is disposed at a distance from the die along a particular axis of the die, and wherein the particular axis is substantially parallel to the second surface; and
second means for connecting the first means for packaging to the second means for packaging, the second means for connecting disposed on the first means for connecting.

30. The apparatus of claim 29, wherein the first means for connecting comprises a copper post, and wherein the second means for connecting comprises a solder bump.
